(19) United States
(12) Patent Application Publication
(10) Pub. No.: US 2026/0011607 A1
(43) Pub. Date: Jan. 8, 2026

(54) Substrate for Semiconductor Fabrication Having Selectively Treated Perimeter and Method of Treating

(71) Applicant: Applied Materials, Inc., Santa Clara, CA (US)

(72) Inventors: Loic Benoit Vincent Robert Jean-Claude CONSTANTIN, Austin, TX (US); Sarah WOZNY, Austin, TX (US)

(21) Appl. No.: 18/763,791

(22) Filed: Jul. 3, 2024

(51) Int. Cl. H01L 21/78; H01L 21/265

(52) U.S. Cl. CPC H01L 21/78; H01L 21/265

(57) ABSTRACT

A substrate for semiconductor fabrication having an interior portion bound by a perimeter, wherein all of the perimeter has been selectively treated to form a hardened perimeter having an increased hardness relative to the interior portion is disclosed herein. Methods to selectively treat a substrate for semiconductor fabrication are also disclosed.

### FIELD

Embodiments of the present disclosure generally relate to a substrate for semiconductor fabrication, and a method of treating a substrate for semiconductor fabrication. In particular, a substrate for semiconductor fabrication having a hardened perimeter.

### BACKGROUND

Glass is attracting significant interest for advanced packaging. Glass panels and wafer form factors targeting PCB, as well as advanced substrates, fan out, and interposer applications are suitable substrates for semiconductor fabrication. Such substrates include those requiring glass or fused silica as core or carrier. However, the brittle nature of glass presents challenges and difficulties during processing and other handling. The edges of the glass or fused silica substrates for semiconductor fabrication are subject to breaking, chipping, and deformation during processing and handling.

Current state-of-the-art technology deposits polymers around the glass edges. Although attractive for panel level edge protection, deposited protection polymers on the edges are not suitable for a variety of uses. In addition, the protection polymer tend to smear foreign materials throughout manufacturing process equipment contributing to yield and productivity loss.

The inventors have observed a need to improve the hardness of the edges of glass or fused silica substrates for semiconductor fabrication to prevent chipping and cracking of the substrates for semiconductor fabrication during manufacturing and handling.

### SUMMARY

A substrate for semiconductor fabrication having a selectively hardened perimeter, and methods for treating a substrate for semiconductor fabrication to form a selectively hardened perimeter are provided herein. In some embodiments, a substrate for semiconductor fabrication comprises an interior portion bound by a perimeter, wherein all of the perimeter has been selectively treated to form a hardened perimeter having an increased hardness relative to the interior portion.

In some embodiments, a method of treating a substrate for semiconductor fabrication comprises selectively treating a perimeter of the substrate for semiconductor fabrication to form a hardened perimeter having an increased hardness relative to an interior portion of the substrate for semiconductor fabrication bounded by the perimeter.

In some embodiments, a method to produce a plurality of semiconductor assemblies comprises selectively ion implanting at least one of a top side and a bottom side of a plurality of portions of a base substrate along a plurality of perimeters, each of the plurality of perimeters outlining a substrate for semiconductor fabrication within a corresponding portion of the base substrate to form a plurality of hardened perimeters, each having an increased hardness relative to an interior portion of each of the outlined plurality of substrates for semiconductor fabrication bounded by the corresponding hardened perimeter; processing the base substrate to form a plurality of semiconductor assemblies within each of the hardened perimeters; and subdividing the base substrate by cutting along each of the hardened perimeters to form the plurality of semiconductor assemblies.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a block diagram depicting a base substrate from which a plurality of substrates for semiconductor fabrication are produced according to embodiments disclosed herein.

FIG. 2 is a block diagram depicting a base substrate having a plurality of portions, each having a perimeter outlining a substrate for semiconductor fabrication according to embodiments disclosed herein.

FIG. 3 is a block diagram depicting the base substrate shown in FIG. 2, having a plurality of semiconductor assemblies disposed within each of the hardened perimeters according to embodiments disclosed herein.

FIG. 4 is a block diagram depicting a substrate for semiconductor fabrication comprising a semiconductor assembly according to embodiments disclosed herein.

FIG. 5 is a perspective view depicting a base substrate having a plurality of perimeters outlining a plurality of substrates for semiconductor fabrication according to embodiments disclosed herein.

FIG. 6 is a flowchart depicting a method of treating a substrate for semiconductor fabrication according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a substrate for semiconductor fabrication having a selectively hardened perimeter, and methods for treating a substrate for semiconductor fabrication to form a selectively hardened perimeter are provided herein.

For purposes herein, semiconductor fabrication may also include wafer processing, die preparation, and IC packaging, and the like.

In embodiments, a substrate for semiconductor fabrication comprises an interior portion bound by a perimeter, wherein all of the perimeter has been selectively treated to form a hardened perimeter having an increased hardness relative to the interior portion. In embodiments, the perimeter has been selectively treated via ion implantation to form the hardened perimeter. In embodiments, the ion implantation utilizes one or more of argon, helium, nitrogen, or oxygen. In embodiments, the hardened perimeter extends from an outer edge of the substrate for semiconductor fabrication towards the interior portion by less than or equal to about 2 mm.

In embodiments, the hardened perimeter comprises a glass. In some embodiments, the substrate for semiconductor fabrication consists essentially of, or consists of glass. In embodiments, the hardened perimeter comprises fused silica or a doped fused silica. In some embodiments, the substrate for semiconductor fabrication consists essentially of, or consists of fused silica or a doped fused silica.

In embodiments, both a top side and a bottom side of the substrate has been selectively treated to form the hardened perimeter.

In embodiments, a method of treating a substrate for semiconductor fabrication, comprises selectively treating a perimeter of the substrate for semiconductor fabrication to form a hardened perimeter having an increased hardness relative to an interior portion of the substrate for semiconductor fabrication bounded by the perimeter. In some embodiments of the method, the selectively treating the perimeter of the substrate for semiconductor fabrication comprises ion implantation. In some embodiments of the method, the ion implantation utilizes one or more of argon, helium, nitrogen, or oxygen. In some embodiments of the method, the ion implantation utilizes a potential of greater than or equal to about 10 kV, at a power from about 0.1 to 10 mA. In some embodiments of the method, the ion implantation utilizes a plurality of ion beams.

In some embodiments of the method, the hardened perimeter extends from an outer edge of the substrate for semiconductor fabrication towards the interior portion by less than or equal to about 2 mm, e.g., the hardened perimeter has a width of 2 mm or less.

In some embodiments of the method, the hardened perimeter comprises glass, fused silica, or a doped fused silica. In some embodiments of the method, both a top side and a bottom side of the substrate has been selectively treated to form the hardened perimeter. In some embodiments, the method further comprises subdividing a base substrate comprising the hardened perimeter by cutting the base substrate along the hardened perimeter to form the substrate for semiconductor fabrication.

In some embodiments, the method further comprises processing of the base substrate to form a semiconductor assembly within the hardened perimeter of the substrate for semiconductor fabrication prior to subdividing the base substrate along the hardened perimeter.

In embodiments, a method to produce a plurality of semiconductor assemblies, comprises selectively ion implanting a top side and a bottom side of a plurality of portions of a base substrate along a plurality of perimeters, each of the plurality of perimeters outlining a substrate for semiconductor fabrication within a corresponding portion of the base substrate to form a plurality of hardened perimeters, each having an increased hardness relative to an interior portion of each of the outlined plurality of substrates for semiconductor fabrication bounded by the corresponding hardened perimeter; processing the base substrate to form a plurality of semiconductor assemblies within each of the hardened perimeters; and subdividing the base substrate by cutting along each of the hardened perimeters to form the plurality of semiconductor assemblies. In some embodiments, the base substrate is glass, fused silica, or a doped fused silica. In some embodiments, the selective ion implanting utilizes one or more of argon, helium, nitrogen, or oxygen, a potential of greater than or equal to about 10 kV, and a power from about 0.1 to 10 mA.

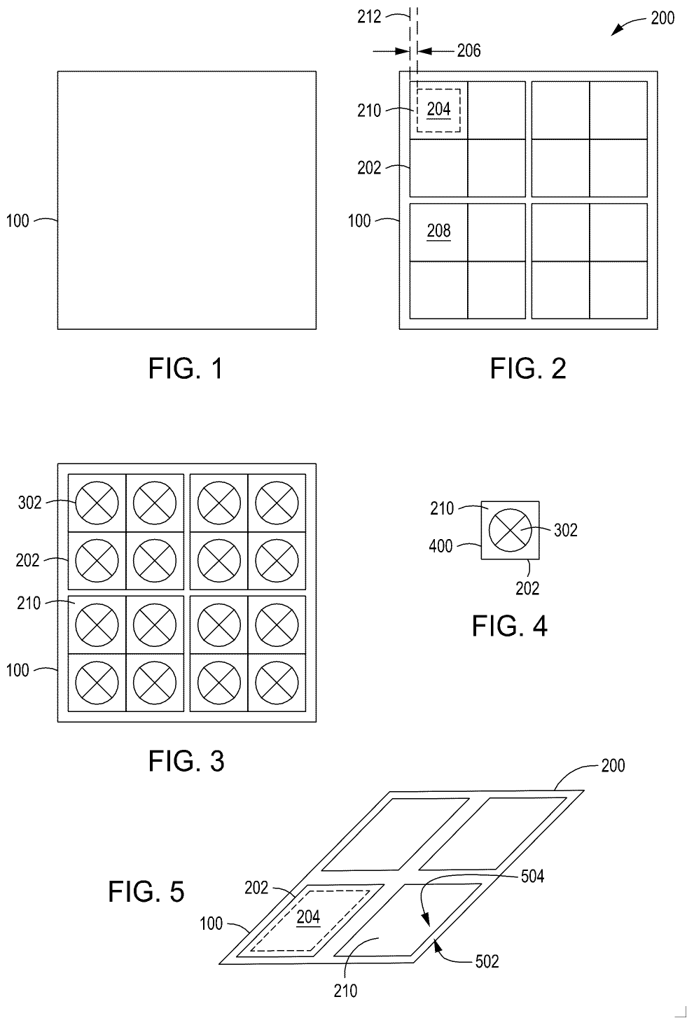

FIG. 1 is a block diagram depicting a base substrate 100 from which a plurality of substrates for semiconductor fabrication may be produced according to embodiments disclosed herein.

In embodiments, the base substrate 100 is formed from glass, from fused silica, or from doped fused silica. In embodiments, the glass substrate may have any thickness suitable for the intended purpose, and may comprise from about 55 wt % to essentially 100 wt % SiO₂. In embodiments, the glass may further comprise Al₂O₃, B₂O₃, Na₂O, CaO, MgO, K₂O, BaO, and/or the like. In embodiments, the glass is a soda-lime glass, an aluminosilicate glass, a borosilicate glass, or an alumino-borosilicate glass.

In embodiments, the substrate is fused silica, which in embodiments is doped with one or more materials suitable for the intended purpose. In embodiments, the fused silica is doped with hydrogen, oxygen, chlorine, fluorine, or a combination thereof.

In embodiments, the base substrate is larger than the substrates for semiconductor fabrication, allowing for a plurality of substrates for semiconductor fabrication to be produced from a single base substrate by subdividing the base substrate along the hardened perimeters resultant from treating of the base substrate according to embodiments disclosed herein.

In embodiments, the base substrate is selectively treated to form a plurality of hardened perimeters of substrates for semiconductor fabrication into the base substrate. The hardened perimeters each have an increased hardness relative to an interior portion of the substrate for semiconductor fabrication bounded by the hardened perimeter.

In embodiments, a panel or wafer level ion implanter system is used to selectively accelerate ions into the base substrate 100 to outline the perimeter of substrates for semiconductor fabrication, thereby changing the mechanical properties of the portions of the base substrate which will eventually form the perimeter of each substrates for semiconductor fabrication.

The ions of the ion implantation modify the glass or fused silica network and chemical composition thus improving the hardness of the perimeter portion. In addition, the selective ion implantation of the perimeters improve the scratch resistance and overall toughness of the edges of the substrates for semiconductor fabrication.

In embodiments, the ion implantation utilizes one or more of argon, helium, nitrogen, or oxygen. In embodiments, the ion implantation utilizes a potential of greater than or equal to about 10 kV, and a power from about 0.1 to 10 mA. However, the properties of the selectively treated portions of the substrate for semiconductor fabrication can be tailored by adjusting the ion current, voltage and/or the type of ions utilized.

In embodiments, argon, helium, nitrogen, and/or oxygen may be used. In embodiments, the acceleration voltage for the extraction of the ions is greater than or equal to about 10 kV, and less than or equal to about 200 kV. In embodiments, the ion dosage is from about 10¹⁴ ions/cm² to about 2.5×10¹⁷ ions/cm². In embodiments, the ions are positively charged species, and implanted into the substrate to a depth of greater than or equal to about 0.1 μm, and less than or equal to about 1 μm.

In embodiments, the temperature of the base substrate during the selective treating of the perimeter is from about 20° C., to less than the glass transition temperature of the substrate.

In embodiments, only the perimeter of the substrate for semiconductor fabrication is selectively treated to form a hardened perimeter. As such, the selectively treated perimeter has an increased hardness relative to the interior portion, which is not treated e.g., via ion implantation, according to embodiments disclosed herein. In other words, only the perimeter is treated, not the entire substrate.

The selective treating via ion implantation may be conducted by either moving one or more ion beams relative to the base substrate and/or moving the base substrate. The ion implantation thus outlines the substrate for semiconductor fabrication within a corresponding portion of the base substrate to form the hardened perimeters of the substrate for semiconductor fabrication, which may be formed on the bare glass.

In embodiments, the ion implantation utilizes a single ion beam. In other embodiments, the ion implantation utilizes a plurality of ion beams.

FIG. 2 is a block diagram depicting a selectively treated base substrate 200 in which the base substrate 100 has been selectively treated according to embodiments disclosed herein to have a plurality of portions 208, only one of which is numbered for clarity. Each of the portions 208 have been selectively treated according to embodiments disclosed herein to include a hardened perimeter 202 outlining a substrate for semiconductor fabrication 210 according to embodiments disclosed herein.

In embodiments, the hardened perimeter 202 has a width extending from an outer edge of the substrate for semiconductor fabrication (indicated by line 212) towards the interior portion 204 which is less than or equal to about 2 mm. In embodiments, the width of the hardened perimeter is greater than or equal to about 0.1 mm and less than or equal to about 2 mm, or less than or equal to about 1 mm, or less than or equal to about 0.5 mm.

FIG. 3 depicts the base substrate having a plurality of semiconductor assemblies 300. The semiconductor assemblies 302 are disposed within each of the hardened perimeters 202, of the selectively treated base substrate 200 wherein the plurality of hardened perimeters 202 outline the plurality of substrates for semiconductor fabrication 210. The semiconductor assemblies may be produced by further processing of the selectively treated base substrate 200, e.g., manufacturing such as TGV formation, RDL fabrication, and the like, wherein the semiconductor assemblies 302 are formed and/or disposed within each of the hardened perimeters 202 of the substrates for semiconductor fabrication 210. The hardened perimeters 202 prevent glass cracking from tools and the like during manufacturing or other processing.

As shown in FIG. 4, depicting a substrate for semiconductor fabrication comprising a semiconductor assembly, the base substrate having a plurality of semiconductor assemblies 300 may be subdivided along each of the hardened perimeters 202 to form a semiconductor assembly 400 comprising a hardened perimeter 202 having an increased hardness relative to an interior portion (204, see FIG. 2) of the substrate for semiconductor fabrication 210.

In embodiments, the base substrate having a plurality of semiconductor assemblies 300 is subdivided by cutting along each of the hardened perimeters 202 to form the plurality of semiconductor assemblies 400. In embodiments, the subdividing is conducted using high-speed diamond blades, and/or the like. The hardened perimeters form edges that prevent glass chipping or cracking when subject to the such high-speed diamond blade, or other subdividing techniques The inventors have further observed that the hardened perimeters of the semiconductor assemblies produced according to embodiments disclosed herein, further impede defect formation during unit assembly and handling.

FIG. 5 is a perspective view depicting a selectively treated base substrate 200. As shown in FIG. 5, in embodiments, both a top side 504 and a bottom side 502 of the substrate for semiconductor fabrication 210 has been selectively treated to form the hardened perimeter 202. In other words, both the top and the bottom of the base substrate are selectively treated to include the hardened perimeter 202 outlining the substrate for semiconductor fabrication 210.

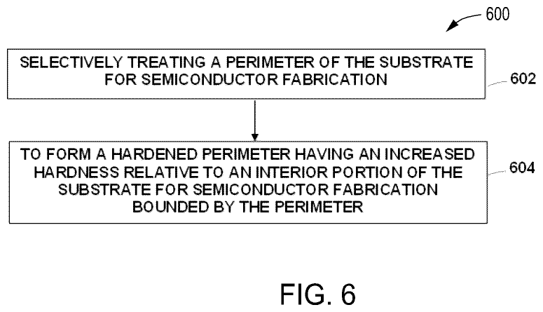

FIG. 6 is a flow chart of a method 600, according to an embodiment of the present disclosure. In embodiments, the method block of FIG. 6 may be performed by a tool, device, and/or processing platform.

FIG. 6 is a flowchart depicting a method of treating a substrate for semiconductor fabrication. As shown in FIG. 6, method 600 may include selectively treating a perimeter of the substrate for semiconductor fabrication (block 602) to form a hardened perimeter having an increased hardness relative to an interior portion of the substrate for semiconductor fabrication bounded by the perimeter (block 604).

While FIG. 6 shows two blocks, in embodiments, method 600 may include other blocks in addition to blocks 602 and 604 depicted in FIG. 6.

While the foregoing is directed to embodiments of the present disclosure, other and further embodiments of the disclosure may be devised without departing from the basic scope thereof.

1. A substrate for semiconductor fabrication, comprising:
an interior portion bound by a perimeter, wherein all of the perimeter has been selectively treated to form a hardened perimeter having an increased hardness relative to the interior portion.

2. The substrate for semiconductor fabrication of claim 1, wherein the perimeter has been selectively treated via ion implantation to form the hardened perimeter.

3. The substrate for semiconductor fabrication of claim 2, wherein the ion implantation utilizes one or more of argon, helium, nitrogen, or oxygen.

4. The substrate for semiconductor fabrication of claim 1, wherein the hardened perimeter extends from an outer edge of the substrate for semiconductor fabrication towards the interior portion by less than or equal to about 2 mm.

5. The substrate for semiconductor fabrication of claim 1, wherein the hardened perimeter comprises glass.

6. The substrate for semiconductor fabrication of claim 1, wherein the hardened perimeter comprises fused silica or a doped fused silica.

7. The substrate for semiconductor fabrication of claim 1, wherein both a top side and a bottom side of the substrate for semiconductor fabrication substrate has been selectively treated to form the hardened perimeter.

8. A method of treating a substrate for semiconductor fabrication, comprising:
selectively treating a perimeter of the substrate for semiconductor fabrication to form a hardened perimeter having an increased hardness relative to an interior portion of the substrate for semiconductor fabrication bounded by the perimeter.

9. The method of claim 8, wherein selectively treating the perimeter of the substrate for semiconductor fabrication comprises ion implantation.

10. The method of claim 9, wherein the ion implantation utilizes one or more of argon, helium, nitrogen, or oxygen.

11. The method of claim 9, wherein the ion implantation utilizes a potential of greater than or equal to about 10 kV, at a power from about 0.1 to 10 mA.

12. The method of claim 9, wherein the ion implantation utilizes a plurality of ion beams.

13. The method of claim 8, wherein the hardened perimeter extends from an outer edge of the substrate for semiconductor fabrication towards the interior portion by less than or equal to about 2 mm.

14. The method of claim 8, wherein the hardened perimeter comprises glass, fused silica, or a doped fused silica.

15. The method of claim 8, wherein both a top side and a bottom side of the substrate for semiconductor fabrication has been selectively treated to form the hardened perimeter.

16. The method of claim 8, further comprising subdividing a base substrate comprising the hardened perimeter by cutting the base substrate along the hardened perimeter to form the substrate for semiconductor fabrication.

17. The method of claim 16, further comprising processing of the base substrate to form a semiconductor assembly within the hardened perimeter of the substrate for semiconductor fabrication prior to subdividing the base substrate along the hardened perimeter.

18. A method to produce a plurality of semiconductor assemblies, comprising:
selectively ion implanting at least one of a top side and a bottom side of a plurality of portions of a base substrate along a plurality of perimeters, each of the plurality of perimeters outlining a substrate for semiconductor fabrication within a corresponding portion of the base substrate to form a plurality of hardened perimeters, each having an increased hardness relative to an interior portion of each of the outlined plurality of substrates for semiconductor fabrication bounded by the corresponding hardened perimeter;
processing the base substrate to form a plurality of semiconductor assemblies within each of the hardened perimeters; and
subdividing the base substrate by cutting along each of the hardened perimeters to form the plurality of semiconductor assemblies.

19. The method of claim 18, wherein the base substrate is glass, fused silica, or a doped fused silica.

20. The method of claim 18, wherein the selective ion implanting utilizes one or more of argon, helium, nitrogen, or oxygen, a potential of greater than or equal to about 10 kV, and a power from about 0.1 to 10 mA.
